(19) United States
(12) Patent Application Publication
(10) Pub. No.: US 2006/0000552 A1
(43) Pub. Date: Jan. 5, 2006

(54) Plasma processing apparatus and cleaning method thereof

(75) Inventors: Hideaki Tanaka, Nirasaki-shi (JP); Yoshimitsu Kon, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/171,186

(22) Filed: Jul. 1, 2005

Related U.S. Application Data
(60) Provisional application No. 60/598,424, filed on Aug. 4, 2004.

(30) Foreign Application Priority Data
Jul. 5, 2004 (JP) 2004-197948

(51) Int. Cl. C23F 1/00; C23C 16/00

(52) U.S. Cl. 156/345.28; 134/1.1; 118/723 R

(57) ABSTRACT

A plasma processing apparatus includes a mounting table for mounting thereon an object to be processed, an electrode connected to a high frequency power supply, an electrical state setting unit for setting an electrical state of the mounting table to a conducting state or a floating state, and a controller for controlling the high frequency power supply to apply a high frequency power to the electrode and controlling the electrical state setting unit to set an electrical state of the mounting table to a floating state. Further, a radical produced from a cleaning gas by the applied high frequency power is made to have a contact with the mounting table.

### CROSS-REFERENCE TO RELATED APPLICATIONS

This document claims priority to Japanese Patent Application Number 2004-197948, filed Jul. 5, 2004 and U.S. Provisional Application No. 60/598,424, filed Aug. 4, 2004, the entire content of which are hereby incorporated by reference.

### FIELD OF THE INVENTION

The present invention relates to a plasma processing apparatus and a cleaning method thereof; and, more particularly, to a plasma processing apparatus including a mounting table for mounting thereon an object to be processed and a cleaning method thereof.

### BACKGROUND OF THE INVENTION

Conventionally, a parallel plate type plasma processing apparatus 40 shown in FIG. 4 is used as one of apparatuses for performing a plasma processing such as a film forming process or an etching process on a wafer W serving as an object to be processed. The plasma processing apparatus 40 includes an upper electrode 42 and a susceptor 43, which are disposed in parallel to face each other, having a specified distance D between electrodes in a chamber 41, and a vacuum exhaust port 44 for maintaining a fixed pressure in the chamber 41.

In the plasma processing apparatus 40, the upper electrode 42 is connected to a high frequency power supply 45, and the susceptor 43 is connected to a high frequency power supply 46, thereby serving as a lower electrode. Further, the upper electrode 42 has a plurality of gas ventholes 47 on its surface facing the susceptor 43. The susceptor 43 has thermally conductive gas supply holes 48 and a thermally conductive gas supply groove (not shown) on its surface facing the upper electrode 42, i.e., the surface for mounting the wafer W thereon.

In the plasma processing apparatus 40, a processing gas is introduced into the chamber 41 and high frequency powers are respectively applied to the upper electrode 42 and the susceptor 43 to generate a plasma from the processing gas, whereby a desired plasma processing is performed on the wafer W. Here, for example, an oxide film or the like is deposited on the susceptor 43 as well as the wafer W in a film forming process, and reaction products are deposited on the susceptor 43 in an etching process. Such reaction products deposited on the susceptor 43 will be attached to the wafer W as foreign substances, which should be regularly removed from the susceptor 43.

A physical etching (sputtering) method has been known as a cleaning method for removing the deposited reaction products from the susceptor 43. In the physical etching method, the wafer W is unloaded from the susceptor 43 and, then, a cleaning gas is ionized to generate ions between the upper electrode 42 and the susceptor 43. At the same time, the susceptor 43 becomes self-biased by applying a high frequency power thereto, whereby the ions collide with the susceptor 43. Accordingly, the deposited reaction products are removed from the susceptor 43 by impact forces of the colliding ions, and the removed reaction products (hereinafter, referred to as “dust”) are discharged through a vacuum exhaust port 44.

Since the dust left in the chamber 41 will be attached to the wafer W, it is necessary to reduce dust generation. As a method for rapidly cleaning the susceptor 43 and reducing the dust generation, there is used a method of setting a distance D between the electrodes in two ways: in a first step when the distance D between the electrodes is set to be small, a high frequency power is applied only to the upper electrode 42 to perform an etching (narrow gap etching), and in a second step when the distance D between the electrodes is set to be large, high frequency powers are applied to both the upper electrode 42 and the susceptor 43 to perform the etching (wide gap etching) (e.g., see Reference 1). Even in the method of setting a distance D between the electrodes in two ways, the deposited reaction products are removed from the susceptor 43 by the impact forces of the colliding ions.

[Reference 1] Japanese Patent Laid-open Publication No. H8-176828

However, when the deposited reaction products are removed from the susceptor 43 by the impact forces of the colliding ions, the ions also erode the susceptor 43. Accordingly, surface roughness becomes worsened on the susceptor 43's surface facing the upper electrode 42, i.e., the surface for mounting the wafer W thereon, and it becomes difficult to seal a thermally conductive gas supplied through the thermally conductive gas supply holes 48 and the thermally conductive gas supply groove, thereby resulting in an increase in a leak rate of a thermally conductive gas between the wafer W and the susceptor 43. If the leak rate of the thermally conductive gas is increased, while a plasma processing is performed on the wafer W, temperature nonuniformity will be developed on the surface of the wafer W, so that the plasma processing cannot be performed uniformly on the wafer W.

### SUMMARY OF THE INVENTION

It is, therefore, an object of the present invention to provide a plasma processing apparatus and a cleaning method thereof capable of removing reaction products deposited on a mounting table therefrom without increasing a leak rate of a thermally conductive gas.

In accordance with a first aspect of the present invention, there is provided a plasma processing apparatus, including a mounting table for mounting thereon an object to be processed; an electrode connected to a high frequency power supply; an electrical state setting unit for setting an electrical state of the mounting table to either a conducting state or a floating state; and a controller for controlling the high frequency power supply to apply a high frequency power to the electrode and controlling the electrical state setting unit to set an electrical state of the mounting table to the floating state, wherein a radical produced from a cleaning gas by the applied high frequency power is made to have a contact with the mounting table. Here, since the electrical state of the mounting table is set to the floating state, a self-bias is not induced in the mounting table. Accordingly, a kinetic energy of an ion colliding with the mounting table is small, whereby erosion of the mounting table does not happen. On the other hand, a radical making a contact with the mounting table reacts chemically with the deposited reaction product to thereby remove it from the top surface of mounting table. Therefore, the reaction products deposited on mounting table can be removed without an increase in a leak rate of a thermally conductive gas.

Preferably, the plasma processing apparatus includes an accommodation chamber for accommodating therein the mounting table and the electrode, the electrode and the mounting table are respectively disposed in an upper portion and a lower portion of the accommodation chamber, and the mounting table is connected to another high frequency power supply. Accordingly, a desired plasma processing can be performed on the object and, at the same time, the mounting table can be properly cleaned.

Preferably, in the plasma processing apparatus, the object is a circular plate having a diameter of 300 mm, and a distance between the mounting table and the electrode is approximately 35 mm. When a distance between the mounting table and the electrode is set to approximately 35 mm in a plasma processing apparatus for performing a plasma processing on an object which is shaped as a circular plate having a diameter of 300 mm, surface roughness is not getting worsened on an object mounting surface of the mounting table by ions' collision. Therefore, it can definitely prevent an increase in the leak rate of the thermally conductive gas.

Preferably, in the plasma processing apparatus, the object is a circular plate having a diameter of 200 mm, and a distance between the mounting table and the electrode is approximately 70 mm. When a distance between the mounting table and the electrode is set to approximately 70 mm in a plasma processing apparatus for performing a plasma processing on an object which is shaped as a circular plate having a diameter of 200 mm, the surface roughness is not getting worsened on an object mounting surface of the mounting table by ions' collision. Therefore, it can definitely prevent an increase in the leak rate of the thermally conductive gas.

In accordance with a second aspect of the present invention, there is provided a cleaning method including the steps of applying a high frequency power to an electrode; setting an electrical state of a mounting table to a floating state; and making a radical produced from a cleaning gas by the applied high frequency power have a contact with the mounting table. When a high frequency power is applied to the electrode, ions and radicals are produced from the cleaning gas near the electrode. Here, if the electrical state of the mounting table is set to a floating state, a self-bias is not induced in the mounting table. Accordingly, the energy of an ion colliding with the mounting table is small, whereby erosion of the mounting table does not happen. On the other hand, a radical made to have a contact with the mounting table reacts chemically with a deposited reaction product to thereby remove it from the top surface of mounting table. Therefore, the reaction products deposited on the mounting table can be removed without an increase in the leak rate of the thermally conductive gas.

In the cleaning method of the plasma processing apparatus, preferably, the object is a circular plate having a diameter of 300 mm, and a distance between the mounting table and the electrode is approximately 35 mm. When a distance between the mounting table and the electrode is set to approximately 35 mm in a plasma processing apparatus for performing a plasma processing on an object which is shaped as a circular plate having a diameter of 300 mm, the surface roughness is not getting worsened on an object mounting surface of the mounting table by ions' collision. Therefore, it can definitely prevent an increase in the leak rate of the thermally conductive gas.

In the cleaning method of the plasma processing apparatus, preferably, the object is a circular plate having a diameter of 200 mm, and a distance between the mounting table and the electrode is approximately 70 mm. When a distance between the mounting table and the electrode is set to approximately 70 mm in a plasma processing apparatus for performing a plasma processing on an object which is shaped as a circular plate having a diameter of 200 mm, the surface roughness is not getting worsened on an object mounting surface of the mounting table by ions' collision. Therefore, it can definitely prevent an increase in the leak rate of the thermally conductive gas.

### BRIEF DESCRIPTION OF THE DRAWINGS

The above and other objects and features of the present invention will become apparent from the following description of preferred embodiments, given in conjunction with the accompanying drawings, in which:

FIG. 1 is a vertical section showing a schematic configuration of a plasma processing apparatus in accordance with a preferred embodiment of the present invention;

FIG. 2 is a flow chart of cleaning processing of a plasma processing apparatus, that is performed in the plasma processing apparatus of FIG. 1;

FIG. 3 is a graph showing a relationship between the total application time of a high frequency power and the leak rate of He gas in an etching process performed after performing the cleaning processing of FIG. 2; and

FIG. 4 shows a schematic configuration of a conventional parallel plate type plasma processing apparatus.

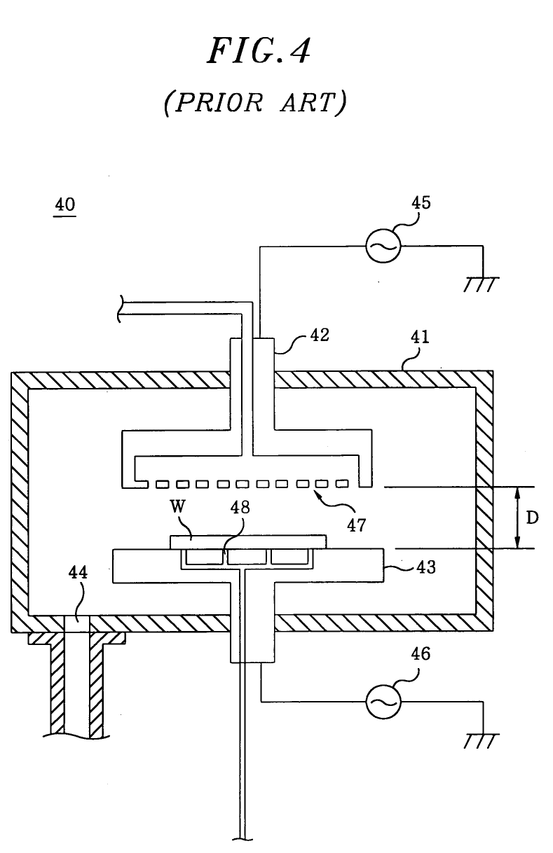

### DETAILED DESCRIPTION OF THE PREFERRED EMBODIMENTS

A preferred embodiment of the present invention will now be described with reference to the accompanying drawings.

Hereinafter, there will be a plasma processing apparatus in accordance with the preferred embodiment of the present invention.

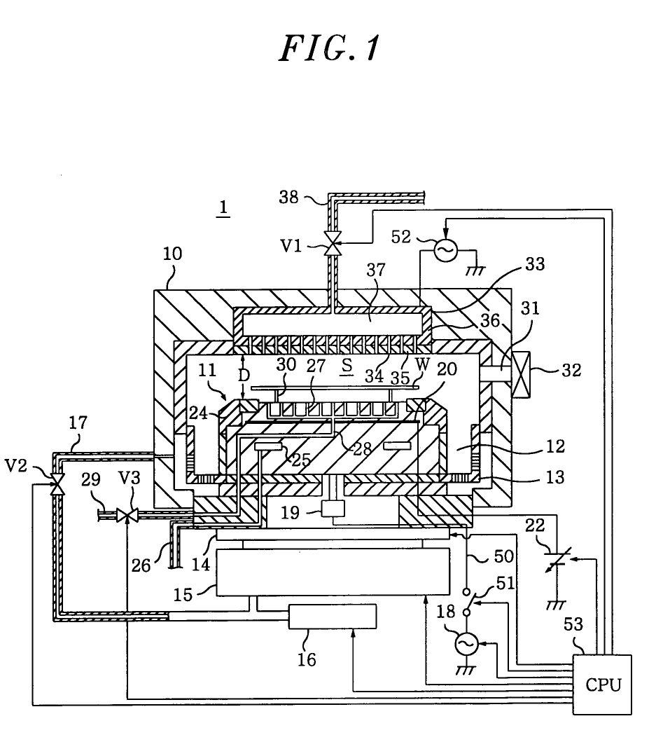

FIG. 1 is a vertical section showing a schematic configuration of the plasma processing apparatus in accordance with the preferred embodiment of the present invention.

A plasma processing apparatus 1 shown in FIG. 1, which is used as an etching processing apparatus for performing an etching process on a wafer (object to be processed) W, includes a cylindrical chamber (accommodation chamber) 10 made of metal such as aluminum or stainless steel, and a cylindrical susceptor (mounting table) 11 serving as a stage for mounting thereon the wafer W having a diameter of, e.g., 300 mm in the chamber 10.

Formed between the sidewall of the chamber 10 and the susceptor 11 is a gas exhaust path 12, which functions as a channel for discharging gas existing above the susceptor 11 to outside of the chamber 10. An annular baffle plate 13 is disposed in the middle of the gas exhaust path 12, and a lower portion of the gas exhaust path 12, which is under the baffle plate 13, is coupled to an automatic pressure control valve 14 (hereinafter, referred to as an “APC”) that is a variable butterfly valve. The APC 14 is connected to a turbo molecular pump 15 (hereinafter, referred to as a “TMP”), which is a gas exhaust pump for vacuum exhaust. Further, the APC 14 is connected to a dry pump 16 (hereinafter, referred to as a “DP”) serving as a gas exhaust pump via the TMP 15. A gas exhaust channel including the APC 14, TMP 15, and DP 16 is hereinafter referred to as a “main pumping line”, wherein the APC 14 controls pressure in the chamber 10 and, additionally, the TMP 15 and DP 16 depressurize the chamber 10 almost to vacuum.

Further, the lower portion of the gas exhaust path 12, which is under the baffle plate 13, is coupled to another gas exhaust channel (hereinafter, referred to as a “rough pumping line”), which is separate from the main pumping line. The rough pumping line includes a gas exhaust pipe 17, having a diameter of, e.g., 25 mm, for connecting the lower portion to the DP 16; and a valve V2 installed in the middle of the gas exhaust pipe 17. The valve V2 can isolate the lower portion from the DP 16. A gas in the chamber 10 is discharged out by the DP 16 in the rough pumping line.

The susceptor 11 is connected to a high frequency power supply 18 via a conducting wire 50, and the high frequency power supply 18 applies a predetermined high frequency power to the susceptor 11, whereby the susceptor 11 functions as a lower electrode. Further, a matching unit 19 and a switch (electrical state setting unit) 51 are installed in the middle of the conducting wire 50, wherein the matching unit 19 reduces a reflection of the high frequency power from the susceptor 11 to thereby optimize an incidence efficiency of the high frequency power to the susceptor 11, and the switch 51 facilitates a changeover between ON and OFF state of the high frequency power supply 18 in the conducting wire 50. Since the switch 51 is inserted between the susceptor 11 and the high frequency power supply 18, the susceptor 11 can be set to one of floating and conducting electrical states. In particular, when the wafer W is not mounted on the top surface of the susceptor 11, the susceptor 11 is set to the floating electrical state.

A circular electrode plate 20, formed of a conductive film, for electrostatically attracting and holding the wafer W is disposed inside an upper portion of the susceptor 11. A DC power supply 22 is electrically connected to the electrode plate 20. The wafer W is attracted and held on the top surface of the susceptor 11 by Coulomb force or Johnsen-Rahbek force produced by a DC voltage applied to the electrode plate 20 from the DC power supply 22. While the wafer W need not be attracted on the top surface, the electrode plate 20 is cut off from the DC power supply 22 to be in a floating state. Further, an annular focus ring 24 formed of silicon (Si) and the like converges plasma produced above the susceptor 11 toward the wafer W.

A coolant chamber 25 of, e.g., a ring shape is provided inside the susceptor 11. A coolant, e.g., cooling water, kept at a specific temperature is supplied to the coolant chamber 25 from a chiller unit (not shown) via a pipe 26 to be circulated therein, whereby the wafer W on the susceptor 11 is controlled to be maintained at a specific process temperature by the coolant.

In the top surface of susceptor 11, thermally conductive gas supply holes 27 and a thermally conductive gas supply groove (not shown) are disposed in a portion which the wafer is attracted to (hereinafter, referred to as an “attracting surface”). Those thermally conductive gas supply holes 27 and the like are connected to a thermally conductive gas feed pipe 29 equipped with a valve V3 via a thermally conductive gas supply line 28 arranged in the susceptor 11. A thermally conductive gas, e.g., He gas, from a thermally conductive gas supply unit (not shown) coupled to the thermally conductive gas feed pipe 29 is supplied into a gap between the attracting surface and the bottom surface of the wafer W though the thermally conductive gas supply holes 27 and the like. Accordingly, heat transfer is improved between the wafer W and the susceptor 11. Further, the valve V3 can isolate the thermally conductive gas supply holes 27 and the like from the thermally conductive gas supply unit.

Further, disposed on the attracting surface is a plurality of pusher pins 30, i.e., lift pins, which can be freely moved up and down from the top surface of the susceptor 11. A rotational movement of a motor (not shown) is converted into a linear movement by ball screws and the like, whereby the pusher pins 30 can be moved vertically. While the wafer W is attracted and held on the attracting surface, an etching process is performed thereon and the pusher pins 30 are accommodated in the susceptor 11, whereas when the wafer W is unloaded from the chamber 10 after the plasma processing completed, the pusher pins 30 are protruded from the top surface of the susceptor 11 such that the wafer W is separated to be lifted from the susceptor 11.

A shower head (upper electrode) 33 is disposed in a ceiling portion of the chamber 10. The shower head 33 is connected to a high frequency power supply 52, which applies a predetermined high frequency power to the shower head 33. Accordingly, the shower head 33 functions as an upper electrode.

The shower head 33 includes an electrode plate 35 having a plurality of gas ventholes 34 on its bottom surface, and an electrode supporting member 36 for attachably or detachably supporting the electrode plate 35. Further, a buffer chamber 37 is provided in the electrode supporting member 36, wherein the buffer chamber 37 is connected to a processing gas inlet pipe 38 extended from a processing gas supply unit (not shown). A valve V1 is installed in the middle of the processing gas inlet pipe 38. The valve V1 can isolate the buffer chamber 37 from the processing gas supply unit. Here, a distance D between the susceptor 11 and the shower head 33 is set to be equal to or larger than, e.g., 35±1 mm.

A gate valve 32 for opening or closing a loading/unloading port 31 of the wafer W is installed on the sidewall of the chamber 10. In the chamber 10 of the plasma processing apparatus 1, as describe above, a high frequency power is applied to the shower head 33, whereby a high-density plasma is generated from the processing gas in a space S and ions or radicals are produced.

Further, the plasma processing apparatus 1 is provided with CPU (controller) 53 inside or outside the apparatus. The CPU 53 is connected to valves V1, V2 and V3, APC 14, TMP 15, DP 16, high frequency power supplies 18 and 52, DC power supply 22 and switch 51, thereby controlling operations of every component in accordance with user's command or a predetermined processing method.

For performing an etching process in the plasma processing apparatus 1, first, after the gate valve 32 is opened, the wafer W serving as an object to be processed is loaded into the chamber 10 and mounted on the susceptor 11. Then, a processing gas having a specified flow rate ratio (e.g., gaseous mixture formed of C₄F₈ gas, O₂ gas and Ar gas having a specified flow rate ratio) is introduced into the chamber 10 at a predetermined flow rate, and a fixed pressure level is maintained in the chamber 10 by the APC 14 and the like. Further, a high frequency power is applied to the susceptor 11 from the high frequency power supply 18 and, at the same time, a high frequency power is applied to the shower head 33 from the high frequency power supply 52. Further, a DC voltage is applied to the electrode plate 20 from the DC power supply 22, whereby the wafer W is attracted and held on the susceptor 11. Then, the processing gas discharged through the shower head 33 is converted into a plasma as described above. Radicals or ions produced by the plasma are converged on the wafer W by the focus ring 24, thereby physically or chemically etching the surface of the wafer W. At this time, reaction products generated by chemical etching are deposited on the top surface of the susceptor 11. The reaction products deposited on the top surface should be removed because they are attached as foreign substances to the bottom surface of the wafer W when the wafer W is mounted on the attracting surface.

As a measure devised to deal with the above problem, in the plasma processing apparatus 1, the top surface of the susceptor 11 is exposed to a space S after the wafer W is unloaded therefrom, and a cleaning gas is supplied into the space S from the shower head 33. Further, the CPU 53 controls the high frequency power supply 52 to apply a high frequency power to the shower head 33. At this time, as mentioned above, the electrical state of the susceptor 11 is set to a floating state by the switch 51. Further, the electrode plate 20 is cut off from the DC power supply 22 to be in a floating state. Accordingly, the radicals produced from the cleaning gas are made to have a contact with the top surface of the susceptor 11, whereby the reaction products deposited on the top surface of the susceptor 11 can be removed therefrom.

Hereinafter, there will be described a cleaning method of a plasma processing apparatus, for removing the reaction products deposited on the top surface of the susceptor 11 in the plasma processing apparatus 1.

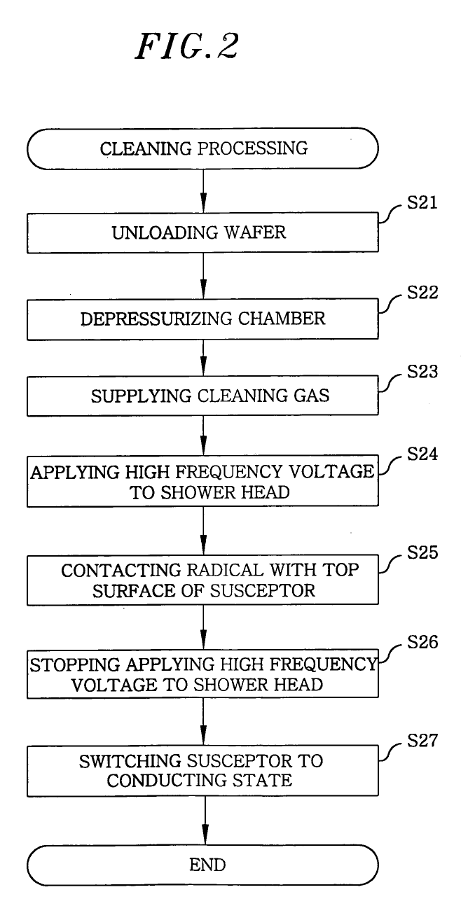

FIG. 2 is a flow chart of cleaning processing of a plasma processing apparatus, wherein the cleaning processing is performed in the plasma processing apparatus shown in FIG. 1 after the etching processing is performed on the wafer W.

In the cleaning processing shown in FIG. 2, first, after the etching processing performed on the last wafer W in, e.g., 1 lot is finished, the pusher pins 30 are protruded from the top surface of the susceptor 11 to lift up the wafer W. Then, the gate valve 32 is opened, and a transfer arm (not shown) is brought into the chamber 10 through the loading/unloading port 31. Thereafter, the transfer arm unloads the wafer W which is raised by the pusher pins 30 to outside of the chamber 10 through the loading/unloading port 31 (step S21). Accordingly, the top surface of the susceptor 11 is exposed to the space S. By this time, the switch 51 has already converted the electrical state of the susceptor 11 into a floating state (floating state setting step). Further, the electrode plate 20 has also been cut off from the DC power supply 22 to be in a floating state.

Subsequently, after the gate valve 32 is closed, the CPU 53 controls the APC 14, TMP 15 and DP 16, so that the chamber 10 is depressurized via the main pumping line or the rough pumping line (step S22) until pressure in the chamber 10 is equal to or lower than a specified value, e.g., 2.67 Pa (20 mTorr). Then, a cleaning gas, e.g., O₂ gas, is supplied into the space S at a specified flow rate, e.g., 600 SCCM (cm³/min, at 1 atm, at 0° C.), through the shower head 33 (step S23).

Thereafter, the CPU 53 controls the high frequency power supply 52 to apply a predetermined high frequency power, e.g., 2000 W, to the shower head 33 (high frequency power applying step, step S24). At this time, a plasma is generated from the cleaning gas near the shower head 33, thereby producing ions or radicals.

Here, since the electrical state of the susceptor 11 is set to a floating state, a large self-bias is not induced in the susceptor 11, and ions are not strongly attracted to the susceptor 11. Accordingly, the kinetic energy of an ion is small when it collides with the top surface of the susceptor 11. As a result, an ion does not remove the deposited reaction products from the top surface of the susceptor 11 by its impact force and, further, does not erode the susceptor 11.

On the other hand, a radical, which reaches the top surface of the susceptor 11 together with an ion, makes a contact with a reaction product deposited on the top surface of the susceptor 11 to chemically react therewith (radical contacting step, step S25), thereby generating another volatile reaction product. The volatile reaction products are easily separated (volatilized) from the top surface of the susceptor 11 to be discharged outside the chamber 10 via the main pumping line or the rough pumping line. Consequently, the reaction products deposited on the top surface of the susceptor 11 can be removed.

Subsequently, when a specific time, e.g., 20 seconds, is elapsed after applying the predetermined high frequency power to the shower head 33, the CPU 53 controls the APC 14, TMP 15 and DP 16 to stop operations of the main pumping line or the rough pumping line and controls the high frequency power supply 52 to stop applying the predetermined high frequency power to the shower head 33 (step S26). Further, the CPU 53 controls the switch 51 to convert the electrical state of the susceptor 11 into a conducting state (step S27), thereby finishing the processing.

In accordance with the processing shown in FIG. 2, a predetermined high frequency power is applied to the shower head 33, and the electrical state of the susceptor 11 is set to the floating state. When a high frequency power is applied to the shower head 33, ions and radicals are generated from the cleaning gas near the shower head 33. At this time, since the electrical state of the susceptor 11 is set to the floating state, a large self-bias is not induced in the susceptor 11. Accordingly, the kinetic energy of the ion colliding with the top surface of the susceptor 11 is small, whereby erosion of the susceptor 11 does not happen. On the other hand, a radical getting in contact with the susceptor 11 reacts chemically with the deposited reaction products on the top surface of the susceptor 11 to thereby remove same therefrom. As a result, the surface roughness will not be worsened on the attracting surface of the susceptor 11. Therefore, the reaction products deposited on the susceptor 11 can be removed without an increase in the leak rate of the thermally conductive gas between the wafer W and the susceptor 11 in plasma processing after cleaning processing.

Further, the plasma processing apparatus 1 includes the chamber 10 for accommodating the susceptor 11 and the shower head 33, wherein the shower head 33 and the susceptor 11 are respectively disposed in an upper portion and a lower portion of the chamber 10 and the susceptor 11 is connected to the high frequency power supply 52. Thus, an etching process can be easily performed on the wafer W in accordance with a desired processing method and, further, so can another plasma processing such as a film forming process. Further, since the susceptor 11 is accommodated in the chamber 10, other reaction products produced in a chemical reaction of radicals can be removed by depressurizing the chamber 10, and the susceptor 11 can be properly cleaned.

The plasma processing apparatus and the cleaning method thereof in accordance with the preferred embodiments of the present invention have been described, but the present invention is not limited thereto.

For instance, the above-mentioned plasma processing apparatus 1 is a parallel plate type plasma processing apparatus including electrodes respectively in an upper portion and a lower portion of the chamber 10, but the present invention can be applied to any plasma processing apparatus as long as it includes a mounting table for mounting thereon the wafer W and an electrode which is connected to a high frequency power supply, for example, a remote plasma processing apparatus such as an electron cyclotron resonance (ECR) plasma processing apparatus or a slot plane antenna (SPA) plasma processing apparatus.

Further, although it is the mounting table that is cleaned in the above plasma processing apparatus 1, an object to be cleaned is not limited thereto, and any component having an electrical state that can be set to a floating state can be cleaned. For example, if an inner wall of the chamber or an upper electrode can be set to have a floating electrical state, the present invention can be applied to them to thereby clean them.

Hereinafter, the preferred embodiments of the present invention will be described in detail.

### Embodiment 1

In the plasma processing apparatus 1, the cleaning processing shown in FIG. 2 was performed under the following conditions.

Pressure in the chamber 10 : 2.67 Pa

Kind of cleaning gas : O₂ gas

Supply flow rate of the cleaning gas : 600 SCCM

High frequency power applied to the shower head 33: 2000 W

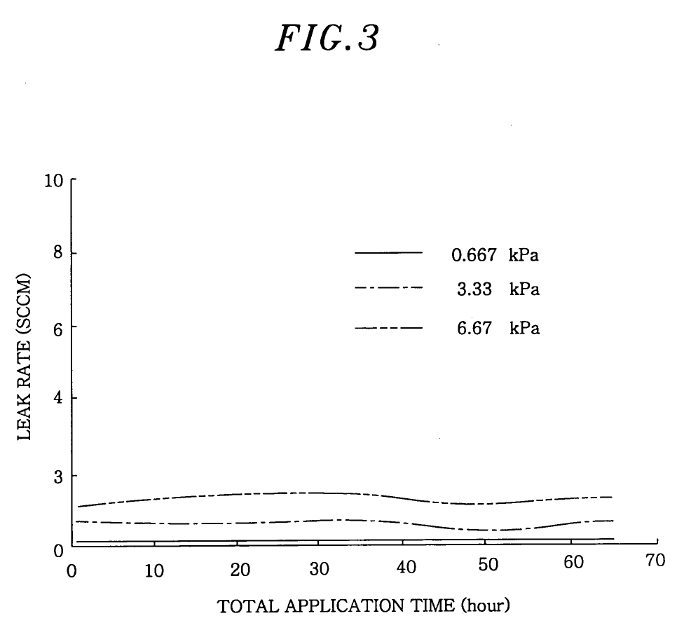

Subsequently, after seasoning, pressure of He gas supplied through the thermally conductive gas supply holes 27 was set to 0.667 kPa, and an etching process was performed on the wafer W. The leak rate of He gas from a gap between the attracting surface and the bottom surface of the wafer W was measured against the total application time (hereinafter, referred to as “total RF time”) of the high frequency power applied to the susceptor 11 and the shower head 33. Then, measurement results are represented by a solid line on a graph of FIG. 3. Further, average surface roughness on the attracting surface was measured at total RF times of O hour, 1300 hours and 3231 hours, respectively.

### Embodiment 2

In the plasma processing apparatus 1, the cleaning processing shown in FIG. 2 was performed under the same conditions as Embodiment 1.

Subsequently, after seasoning, pressure of He gas supplied through the thermally conductive gas supply holes 27 was set to 3.33 kPa, and an etching process was performed on the wafer W. The leak rate of He gas from a gap between the attracting surface and the bottom surface of the wafer W was measured against the total RF time of the high frequency power applied to the susceptor 11 and the shower head 33. Then, measurement results are represented by a dashed dotted line on the graph of FIG. 3. Further, the average surface roughness on the attracting surface was measured at total RF times of O hour, 1300 hours and 3231 hours, respectively.

### Embodiment 3

In the plasma processing apparatus 1, the cleaning processing shown in FIG. 2 was performed under the same conditions as Embodiment 1.

Subsequently, after seasoning, the pressure of He gas supplied through the thermally conductive gas supply holes 27 was set to 6.67 kPa, and an etching process was performed on the wafer W. The leak rate of He gas from a gap between the attracting surface and the bottom surface of the wafer W was measured against the total RF time of the high frequency power applied to the susceptor 11 and the shower head 33. Then, measurement results are represented by a dashed double-dotted line on the graph of FIG. 3. Further, average surface roughness on the attracting surface was measured at total RF times of O hour, 1300 hours and 3231 hours, respectively.

In each embodiment, after the cleaning processing shown in FIG. 2 was performed, it was observed by the naked eye that the reaction products deposited on the top surface (attracting surface) of the susceptor 11 were removed therefrom.

Further, as illustrated in FIG. 3, in an etching process performed after the cleaning processing of FIG. 2 in each embodiment, leak rates of He gas are very small and, specifically, even at a total RF time of 600 hours (not shown), an allowable leak rate of He gas is equal to or less than 2 SCCM.

In the above embodiments 1 to 3, the surface roughness of the attracting surface was 0.13 μm at a total RF time of 0 hour; 0.19 μm at a total RF time of 1300 hours; and 0.27 μm at a total RF time of 3231 hours, which rarely changed. Accordingly, it is found that ions do not erode the susceptor 11.

In accordance with the plasma processing apparatus shown in FIG. 1 and the cleaning processing shown in FIG. 2, as described above, the reaction products deposited on the top surface of the susceptor 11 can be removed without increasing a leak rate of He gas.

Further, the diameter of the wafer W is 300 mm and the distance D between the electrodes, i.e., the susceptor 11 and the shower head 33, was set to 35±1 mm in the plasma processing apparatus 1 of the embodiments 1 to 3, but the same results as in the plasma processing apparatus 1 were obtained in another plasma processing apparatus, wherein the diameter of the wafer W was 200 mm and the distance D between the electrodes was set to 70±1 mm.

While the invention has been shown and described with respect to the preferred embodiments, it will be understood by those skilled in the art that various changes and modifications may be without departing from the spirit and scope of the invention as defined in the following claims.

What is claimed is:

1. A plasma processing apparatus, comprising:
a mounting table for mounting thereon an object to be processed;
an electrode connected to a high frequency power supply;
an electrical state setting unit for setting an electrical state of the mounting table to a conducting state or a floating state; and
a controller for controlling the high frequency power supply to apply a high frequency power to the electrode and controlling the electrical state setting unit to set an electrical state of the mounting table to a floating state,
wherein a radical produced from a cleaning gas by the applied high frequency power is made to have a contact with the mounting table.

2. The plasma processing apparatus of claim 1, wherein the plasma processing apparatus includes an accommodation chamber for accommodating therein the mounting table and the electrode; the electrode and the mounting table are respectively disposed in an upper portion and a lower portion of the accommodation chamber; and the mounting table is connected to another high frequency power supply.

3. The plasma processing apparatus of claim 1, wherein the object is a circular plate having a diameter of 300 mm, and a distance between the mounting table and the electrode is approximately 35 mm.

4. The plasma processing apparatus of claim 1, wherein the object is a circular plate having a diameter of 200 mm, and a distance between the mounting table and the electrode is approximately 70 mm.

5. The plasma processing apparatus of claim 2, wherein the object is a circular plate having a diameter of 300 mm, and a distance between the mounting table and the electrode is approximately 35 mm.

6. The plasma processing apparatus of claim 2, wherein the object is a circular plate having a diameter of 200 mm, and a distance between the mounting table and the electrode is approximately 70 mm.

7. A cleaning method of a plasma processing apparatus including a mounting table for mounting thereon an object to be processed and an electrode connected to a high frequency power supply, the cleaning method comprising the steps of:
applying a high frequency power to the electrode;
setting an electrical state of the mounting table to a floating state; and
making a radical produced from a cleaning gas by the applied high frequency power have a contact with the mounting table.

8. The cleaning method of the plasma processing apparatus of claim 7, wherein the object is a circular plate having a diameter of 300 mm, and a distance between the mounting table and the electrode is approximately 35 mm.

9. The cleaning method of the plasma processing apparatus of claim 7, wherein the object is a circular plate having a diameter of 200 mm, and a distance between the mounting table and the electrode is approximately 70 mm.
